(19) United States
(12) Patent Application Publication
(10) Pub. No.: US 2008/0312463 A1
(43) Pub. Date: Dec. 18, 2008

(54) Organic Silane Compound, Method of Producing the Same, and Organic Thin Film Using the Same

(76) Inventors: Hiroshi Imada, Nara (JP); Hiroyuki Hanato, Nara (JP); Toshihiro Tamura, Nara (JP)

Correspondence Address: NIXON & VANDERHYE, PC, 901 NORTH GLEBE ROAD, 11TH FLOOR, ARLINGTON, VA, 22203, US

(21) Appl. No.: 11/658,502

(22) PCT Filed: Aug. 17, 2005
(86) PCT No.: PCT/JP2005/014996

§ 371 Date: Jan. 25, 2007

(30) Foreign Application Priority Data
Aug. 24, 2004 (JP) 2004-243510

(51) Int. Cl. C07F 7/02

(52) U.S. Cl. 556/482

(57) ABSTRACT

The present invention provides a highly ordered, crystallized organic thin film superior in electroconductive properties that is resistant to exfoliation, a compound for preparation of the thin film, and a method of producing the same.

An organic silane compound, characterized in that a molecule represented by General Formula (I) is substituted with a silyl group.

A method of producing the organic silane compound, comprising halogenating a molecule (I) and allowing it to react with a silane derivative.

An organic thin film, wherein the organic silane compound molecule is oriented with its silyl group located in the substrate side and the molecule (I) region in the film surface side.

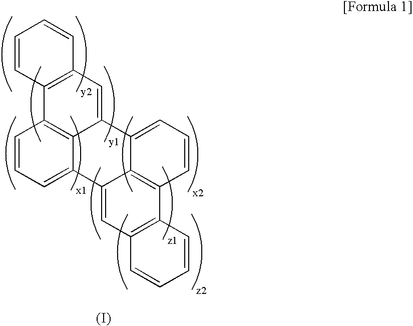

(wherein, x1 and x2 are integers satisfying 1≦x1, 1≦x2, and 2≦x1+x2≦8; each of y1 and z1 is independently an integer of 2 to 8; each of y2 and z2 is independently an integer of 0 to 8; and the skeleton may be substituted with a hydrophobic group).

### TECHNICAL FIELD

The invention relates to an organic silane compound, a method of producing the compound, and an organic thin film using the compound.

### BACKGROUND ART

Recently under progress is research and development on semiconductors of organic compound, because these semiconductors are simpler in production than semiconductors of inorganic material, allow cost down by mass production, and have functions wider in variety than those from an inorganic material, and such organic semiconductors have been reported.

The compound most intensively studied as a material for organic devices is pentacene. It is because pentacene, which has a very small band gap and a rigid structure, can be used for production of organic devices with superior characteristics, if it is highly oriented. Vacuum deposition has been used as a method of forming such a pentacene thin film. It is because pentacene is scarcely soluble in solvent and thus it was difficult to form a thin film in a solution process.

On the other hand, proposed as an organic device prepared by using a compound other than pentacene in the solution process was, for example, an organic device using a semiconductor layer of an electroconductive thin film prepared by using an organic silane compound of a thiophene ring having two straight-chain hydrocarbon groups respectively bound to the 2- and 5-positions and additionally a silyl group bound to the terminal of the straight-chain hydrocarbon, forming a self-structured film thereof on a substrate, and converting it into a conductive thin film by polymerization of the molecules therein for example by electric-field polymerization (for example, Patent Document 1).

Also proposed is a electric-field transistor prepared by using a semiconductor thin film mainly containing an organic silane compound having a silyl group bound to the thiophene ring contained in polythiophene as the principal component (for example, Patent Document 2).

### Patent Document 1: Japanese Patent No. 2507153

### Patent Document 2: Japanese Patent No. 2725587

### DISCLOSURE OF THE INVENTION

### Technical Problems to be Solved

As described above, pentacene is generally less soluble in solvent and filmed by vapor deposition, and the vapor deposition method gave a film lower in orientation, less compatible with the substrate, and consequently lower in orientation, causing problem that the properties of the resulting device varied significantly depending on the substrate used. On the other hand, it is possible to improve orientation by performing an orientation treatment such as rubbing previously, but such a method has a disadvantage of making the film-making process more complicated. In addition, filming by vapor deposition, which gives a film physically adsorbed on the substrate, carried problems of low film durability and faster deterioration.

There was also a concern on electroconductive thin films formed by electric-field polymerization of an organic silane compound about wider variation in field-effect mobility due to unevenness of polymerization degree, depending on the device used. In addition, a semiconductor thin film of an organic silane compound containing polythiophene has a very great number of silyl groups adsorbed on the polymer although the film thickness of the semiconductor is greater, and does not allow control of the adsorption reaction with a substrate only by self structuring, making it difficult to form a highly crystallized thin film.

Further, conventional known organic thin films have bonds directed both in the molecular direction and the direction perpendicular to the molecular direction, and thus, when used in an organic thin film transistor, gives a greater leak current and consequently deteriorates the properties of the device.

Thus, it is needed to orient a compound, such as pentacene, higher in electric conductance in the film state efficiently in high order, in order to obtain superior device characteristics, but there is still no such an organic thin film prepared by conventional methods that can overcome the problems above.

An object of the invention, which was made under the circumstances above, is to provide a compound for preparation of a highly ordered, crystallized organic thin film superior in electroconductive property that can be formed easily by crystallization in a simple production method, and is resistant to physical exfoliation because of tight adsorption of the thin film onto the substrate surface, and a method of producing the same.

### Means to Solve the Problems

The invention relates to an organic silane compound, characterized in that a fused polycyclic aromatic hydrocarbon molecule represented by General Formula (I) is substituted with a silyl group represented by General Formula: —SiR¹R²R³ (wherein, R¹ to R³ each independently represents a halogen atom or an alkoxy group having 1 to 4 carbon atoms)

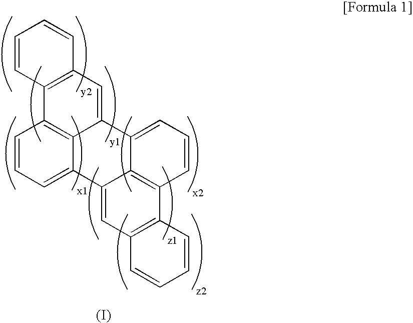

(wherein, x1 and x2 are integers respectively satisfying 1≦x1, 1≦x2, and 2≦x1+x2≦8; each of y1 and z1 is independently an integer of 2 to 8; each of y2 and z2 is independently an integer of 0 to 8; and the molecule may be substituted with hydrophobic groups).

The invention also relates to a method of producing the organic silane compound, comprising halogenating the fused polycyclic aromatic hydrocarbon molecule and introducing an silyl group in reaction thereof with a compound represented by General Formula (a);

X¹—SiR¹R²R³ (α)

(wherein, X¹ represents a hydrogen or halogen atom or an alkoxy group having 1 to 4 carbon atoms; and R¹ to R³ each independently represents a halogen atom or an alkoxy group having 1 to 4 carbon atoms).

The invention also relates to an organic thin film, comprising the organic silane compound formed on a substrate, wherein the organic silane compound molecule is oriented with its silyl group located in the substrate side and the fused polycyclic aromatic hydrocarbon molecule region in the film surface side.

### EFFECTS OF THE INVENTION

The organic silane compound according to the invention, which has a terminal silyl group, forms a network of silicon and oxygen atoms among neighboring compound molecules and binds to the substrate chemically via a silanol bond, for example, when an organic thin film is formed. As a result, the organic thin film is very highly stabilized and highly crystallized. Thus, the thin film obtained is adsorbed on the base material surface more tightly than the film physically adsorbed on the base material, preventing physical exfoliation effectively.

In addition, the organic silane compound according to the invention has a fused polycyclic aromatic hydrocarbon skeleton that is π-electron conjugated; high π-electron interaction and intermolecular interaction (van der Waals interaction) are generated among neighboring molecules in an organic thin film; and thus, the resulting film obtained is superior in semiconductor characteristics and higher in crystallinity.

Further, the organic silane compound according to the invention becomes more soluble, when it has a hydrophobic group as the side chain. It is thus possible to use a relatively simpler method, i.e. solution process, for example, in forming a thin film. Among the compounds according to the invention, compounds having a straight-chain hydrocarbon group are more soluble.

Because of these characteristics, the compound according to the invention, which gives an orientated organic thin film easily, can be used not only in the field of organic thin film transistor but also in the fields of solar cell, fuel cell, sensor, and others as an electroconductive or semiconductor material.

### BRIEF DESCRIPTION OF THE DRAWINGS

FIG. 1 is a schematic diagram illustrating the molecular orientation of the organic thin film (unimolecular film) formed by using an organic silane compound according to the invention.

### EXPLANATION OF NUMERALS

1: Silicon substrate
2: Silicon-oxygen network structure
3: Fused polycyclic aromatic hydrocarbon molecule region

### BEST MODE FOR CARRYING OUT THE INVENTION

(Organic Silane Compound)

The organic silane compound according to the invention is a compound in which a fused polycyclic aromatic hydrocarbon molecule is substituted with a silyl group.

The fused polycyclic aromatic hydrocarbon molecule is represented by General Formula (I):

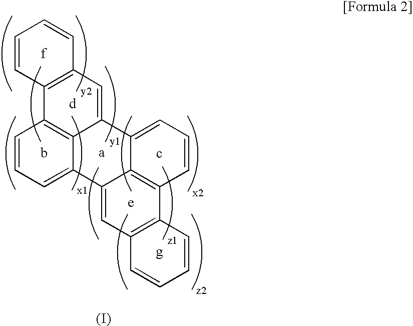

(hereinafter, the molecule represented by General Formula (I) will be referred to as “molecule (I)”).

In Formula (I), x1 and x2 are integers, respectively satisfying 1≦x1, 1≦x2, and 2≦x1+x2≦8. x1 represents the number of fused rings b present to the left of the ring a in General Formula (I) above. Increase in x1 means that there are more fused rings, leftward from ring b. x2 represents the number of fused rings c present to the right of the ring a in General Formula (I) above. Increase in x2 means that there are more fused rings, rightward from the ring c.

Preferable, each of x1 and x2 is independently an integer of 1 to 2, more preferable 1 at the same time.

Each of y1 and z1 is independently an integer of 2 to 8. y1 represents the number of the fused rings d in General Formula (I) above. Increase in y1 means that there are more fused rings, leftward and/or rightward from the ring d. z1 represent the number of the fused rings e in General Formula (I) above. Increase in z1 means that there are more fused rings, leftward and/or rightward from the ring e.

Each of y1 and z1 is preferably, independently an integer of 2 to 3, more preferable, 2 at the same time.

Each of y2 and z2 is independently an integer of 0 to 8. y2 represents the number of the fused rings f in General Formula (I) above. Increase in y2 means that there are more fused rings, leftward and/or rightward from the ring f. z2 represents the number of the fused rings g in General Formula (I) above. Increase in z2 means that there are more fused rings, leftward and/or rightward from the ring g.

Each of y2 and z2 is preferably, independently an integer of 0 to 2, more preferable 0 at the same time.

It is possible to reduce the energy difference of the HOMO-LUMO band gap by using such a molecule (I). Generally, in the case of a fused polycyclic aromatic hydrocarbon molecule, the energy difference of HOMO-LUMO band gap varies according to the size of the molecule and the direction of fusion. To reduce the energy difference of HOMO-LUMO band gap, it is preferable that the number of the rings contained in the fused polycyclic aromatic hydrocarbon molecule is greater and that the molecule has a branched-shape. Thus in the fused polycyclic aromatic hydrocarbon molecule, it is possible to reduce the energy difference of HOMO-LUMO band gap by increasing the number of constituent rings and making the molecule have a branched structure containing many resonance structures, as in molecule (I). The branched structure is defined by the number of the carbon atoms shared by three rings (hereinafter, referred to as triple point atoms) and the number of resonance structures. When the total ring number is about 10 or less, the combination of the numbers of triple point atoms and resonance structures is preferably (4,2), more preferably (6,2).

The molecule (I) is preferably symmetrical (for example, axisymmetrical or point symmetrical) from the viewpoint of orientation of the molecules in organic thin film, more preferably both axisymmetrical and point-symmetrical.

Typical favorable examples of the molecule (I) include the compounds shown below.

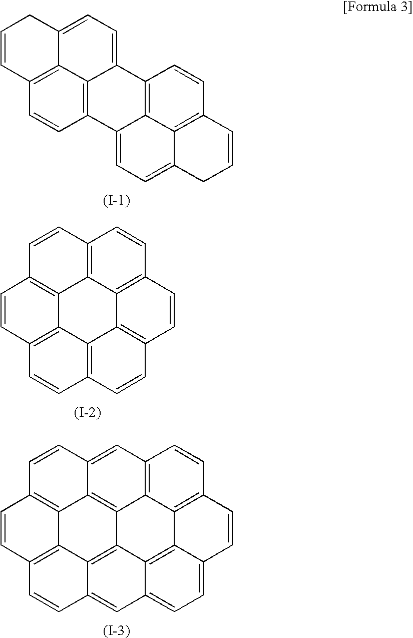

For example, the compound represented by Formula (I-1) is a compound molecule represented by General Formula (I) above wherein x1=x2=1, y1=z1=2, and y2=z2=0. The compound can be prepared in reaction of perylene with SbF₅—SO₂ClF. Perylene, a known substance registered as CAS. No. 198-55-0, is commercially available.

The compound represented by Formula (I-2) is a compound molecule represented by General Formula (I) above wherein x1=x2=1, y1=z1=2, and y2=z2=0. The compound, a known compound registered as CAS. No. 191-07-1, is commercially available.

The compound represented by Formula (I-3) is a compound molecule represented by General Formula (I) above wherein x1=2, x2=1, y1=z1=3, and y2=z2=0. The compound, a known substance registered as CAS. No. 190-26-1, is commercially available.

The molecule (I) may have not only a silyl group described below but also a hydrophobic group as needed. Presence of a hydrophobic group improves solubility in organic solvent and the surface activity of molecule further. The hydrophobic group may be any group, if it has a HLB parameter, an indicator of the hydrophilicity or hydrophobicity, of 0 or less. The HLB (Hydrophilic-Lypophilic Balance) is a numerical value needed for determining whether a molecule is hydrophilic or hydrophobic, and each functional group has its own parameter. For example, a methylene group has a HLB value of −0.475, while a carboxyl group, +2.1.

Examples of the hydrophobic groups include alkyl, oxyalkyl, fluoroalkyl, and fluoro groups, and the like. The alkyl, oxyalkyl, and fluoroalkyl groups preferably have a carbon number of 1 to 30, particularly preferably 1 to 10. In particular, film orientation is preferably as high as possible, when the film is used in an organic device, and thus, a straight-chain alkyl group having a carbon number in the range above is preferable from the viewpoint of molecular alignment. Typical examples of the straight-chain alkyl groups include methyl, ethyl, n-propyl, n-butyl, n-pentyl, n-hexyl, n-heptyl, n-octyl, n-nonyl, and n-decyl groups, and the like.

One or more hydrophobic groups may be bound thereto. The binding site of the hydrophobic group is not particularly limited, but the site where molecular alignment in film is not inhibited is preferable from the viewpoint of molecular alignment. For example when the molecule (I) is symmetrical, the hydrophobic group is preferably bound to the site opposite to the binding site of the silyl group. When two or more hydrophobic groups are bound, all hydrophobic groups may be the same as each other or part or all of them are different from each other.

The silyl group bound to the molecule (I) is represented by the following General Formula:

—SiR¹R²R³

and in the present invention, one or two such silyl groups are bound to the molecule (I).

R¹ to R³ in the silyl group each independently represents a halogen atom or an alkoxy group having 1 to 4 carbon atoms. The alkoxy group is preferably a straight-chain group.

Typical examples of the alkoxy groups include methoxy, ethoxy, n-propoxy, 2-propoxy, n-butoxy, sec-butoxy, and tert-butoxy groups, and the like. Part of the hydrogen atoms in the alkoxy group may be replaced with another substituent such as a trialkylsilyl group (with an alkyl group having 1 to 4 carbon atoms) or an alkoxy group (having 1 to 4 carbon atoms).

Examples of the halogen atoms include fluorine, chlorine, iodine, and bromine atoms, but the halogen atom is preferably a chlorine atom, considering reactivity.

Preferably, R¹ to R³ each independently represents a chlorine atom or an alkoxy group having 1 to 2 carbon atoms, and more preferably, they are the same groups.

(Production Method)

The organic silane compound according to the present invention can be prepared by halogenating the molecule (I) above and introducing a silyl group into the molecule in reaction thereof with a compound represented by General Formula (α);

X¹−SiR¹R²R³ (α)

(wherein, X¹ represents a hydrogen or halogen atom or an alkoxy group having 1 to 4 carbon atoms; and R¹ to R³ are respectively the same as R¹ to R³ in the silyl group).

The molecule is halogenated by halogenating a particular site in the molecule in a solvent such as carbon tetrachloride, for example, with N-chlorosuccinimide (NCS) or N-bromosuccinimide (NBS). The solvent for use is, for example, chloroform, acetic acid, or the mixture thereof.

In introducing the silyl group, the reaction temperature is preferably, for example, −100 to 150° C., more preferably −20 to 100° C. The reaction period is, for example, approximately 0.1 to 48 hours. The reaction is normally carried out in an organic solvent inert to the reaction. Examples of the organic solvents inert to the reaction include aliphatic or aromatic hydrocarbons such as hexane, pentane, benzene and toluene, ether solvents such as diethylether, dipropylether, dioxane and tetrahydrofuran (THF), and the like, and these solvents may be used alone or as a liquid mixture. Among the solvents above, diethylether and THF are favorable. A catalyst may be used in the reaction as needed. Any one of known catalysts such as platinum catalysts, palladium catalysts, and nickel catalysts may be used as the catalyst. The reaction is preferably carried out in the presence of an alkyllithium such as n-BuLi, from the viewpoint of yield.

Typical favorable examples of the compounds (α) include tetraethoxysilane, tetrachlorosilane, and the like.

The hydrophobic group can be introduced by halogenating a particular site of the molecule (I) and allowing it to react with a hydrophobic group-containing compound. The hydrophobic group-containing compound is a compound which can introduce its hydrophobic group to the site in reaction with the halogenated site of molecule (I). Specifically, for example, when the hydrophobic group is an alkyl or fluoroalkyl group, a Grignard reagent having the hydrophobic group may be used. Alternatively, for example, when the hydrophobic group is an oxyalkyl group, an alcohol containing the group may be used.

The reaction condition for introducing the hydrophobic group is not particularly limited, if the hydrophobic group can be actually introduced, but the reaction is normally carried out under reflux in an organic solvent inert to the reaction for 1 to 48 hours. The organic solvent for use in the reaction of introducing a silyl group can also be used as the organic solvent inert to the reaction.

The organic silane compound thus obtained may be isolated from a reactive solution and purified by any one of known means such as resolubilization, concentration, solvent extraction, fractionation, crystallization, recrystallization, chromatography, and the like.

(Organic Thin Film and Method of Forming the Same)

An organic thin film (in particular, unimolecular film) can be formed by using the organic silane compound according to the invention. Preferably, the unimolecular film is formed on a substrate.

R¹ and R² in the silyl group of the organic silane compound according to the present invention are easily hydrolyzed, and thus, the silyl group is relatively higher in hydrophilicity and improves the surface activity of the entire molecule. Accordingly, for example, when a film of the compound according to the present invention is formed on a hydrophilic substrate, the silyl group contained in the compound according to the invention, interacting with the substrate, orients all molecules aligned in the same direction and adsorbs efficiently on the substrate, consequently forming chemical bonds. It is thus possible to shorten the reaction period and improve orientation of the thin film. Fused polycyclic aromatic hydrocarbon molecules, in particular those containing eight or more fused rings, are generally less soluble in organic solvent, but introduction of a hydrophobic group into an organic silane compound according to the invention leads to improvement in solubility. It also leads to further improvement in the surface activity of the entire molecule and allows shortening of the reaction period of film formation and improvement in orientation of the thin film more effectively.

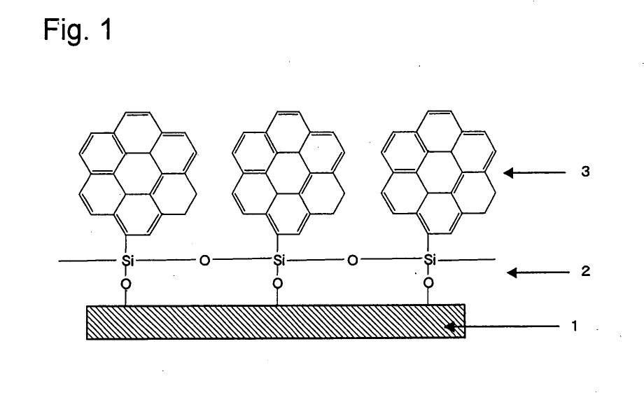

An organic thin film of the organic silane compound according to the present invention will be described with reference to FIG. 1. FIG. 1 is a schematic view of an organic thin film of the organic silane compound according to the invention having the molecular skeleton represented by the Formula (I-2) above.

As shown in FIG. 1, the organic silane compound molecules are oriented in the organic thin film in such a manner that the silyl group 2 is located in the substrate side 1 and the fused polycyclic aromatic hydrocarbon molecule region 3 in the film surface side. The compound molecule, which is bound to the substrate via a chemical bond (in particular, silanol bond (—Si—O—)) with its silyl group, gives an organic thin film higher in durability. In addition, a network 3 of silicon and oxygen atoms is formed in reaction among the silyl groups of neighboring molecules, and thus, the intermolecular distance between neighboring molecules is reduced effectively. The fused polycyclic aromatic hydrocarbon molecule region 3 in the organic silane compound molecule is π-electron conjugated, and the intermolecular distance among them is kept smaller by the network 3, and, for that reason, the organic thin film becomes higher in electroconductivity. The fused polycyclic aromatic hydrocarbon molecule regions 3 are not bound to each other in the organic thin film and thus, the conductivity is kept low in the normal state, and the conductivity becomes higher only when a carrier that can be photoexcited or electric-field excited is injected into the organic thin film.

The substrate is not particularly limited. Examples thereof include single-layered or laminate films of semiconductors including element semiconductors such as silicon and germanium and compound semiconductors such as GaAs, InGaAs, and ZnSe; so-called SOI substrates, multilayer SOI substrates, and SOS substrates; mica; glass and quartz glass; insulators such as polymer film of polyimide, PET, PEN, PES, Teflon, or the like; stainless steel (SUS); metals such as gold, platinum, silver, copper, and aluminum; high melting-point metals such as titanium, tantalum, and tungsten; silicides and polycides of a high melting point metal; silicon oxide films (such as heat-oxidized film, low-temperature-oxidized film (LTO film), high-temperature-oxidized film (HTO film)), insulators such as silicon nitride film, SOG film, PSG film, BSG film, and BPSG film; PZT, PLZT, and ferro-electric and antiferro-electric substances; low-dielectric films such as SiOF film, SiOC film and CF film, HSQ (hydrogen silsesquioxane) film (inorganic), MSQ (methyl silsesquioxane) film, PAE (polyarylene ether) film, and BCB film, porous film formed by coating, CF film, and porous films; and the like. The substrate may be an inorganic material for use as an electrode in semiconductor devices and may have an additional film of organic material formed on the surface thereof.

In the invention, the substrate surface has hydrophilic groups such as hydroxyl and carboxyl, in particular hydroxyl groups, and, if not, hydrophilic groups may be generated on the substrate surface by a hydrophilizing treatment. For example, the substrate may be hydrophilized by immersing it in a mixed hydrogen peroxide-sulfuric acid solution or by irradiation of the substrate with UV light.

Hereinafter, the method of forming an organic thin film will be described.

In forming an organic thin film, the organic silane compound according to the present invention is allowed to react with the substrate surface by hydrolysis of the silyl group, forming an unimolecular film directly adsorbed (bound) to the substrate. Specifically, a method such as so-called LB method (Langmuir Blodgett method), dipping method, or coating method may be used.

More specifically, for example in the LB method, an organic silane compound is dissolved in a nonaqueous organic solvent, and the solution obtained is applied dropwise onto the surface of water previously pH-adjusted, forming a thin film thereon. The groups R¹ to R³ in the silyl group of the organic silane compound are then hydrolyzed into hydroxyl groups. Subsequent application of pressure on the water surface in that state and withdrawal of the substrate with the surface carrying the hydrophilic groups formed (in particular, hydroxyl groups) leads to reaction of the silyl groups in the organic silane compound with the substrate, giving a unimolecular film bound via chemical bonds (in particular, silanol bonds) to the substrate. A network of silicon and oxygen atoms is also formed then in reaction between the silyl groups in neighboring molecules. The pH of water on which the solution is applied dropwise is preferably adjusted to a pH allowing hydrolysis of the groups R¹ to R³.

Alternatively, in the dipping method and the coating method, an organic silane compound is dissolved in a nonaqueous organic solvent, and a substrate having hydrophilic groups (in particular, hydroxyl groups) on the surface is dipped in the solution obtained and then withdrawn therefrom, or the solution obtained is coated on the surface of the base material. The groups R¹ to R³ in the silyl group of the organic silane compound are then hydrolyzed into hydroxyl groups by the water present in a trace amount in the nonaqueous solvent. The silyl groups in the organic silane compound are then bound to the substrate in reaction when the dipped substrate is held as it is for a particular period, forming chemical bonds (in particular, silanol bonds) and consequently giving an unimolecular film. A network of silicon and oxygen atoms is also formed in reaction between the silyl groups in neighboring molecules. When the groups R¹ to R³ are not hydrolyzed, it is preferable to add a small amount of pH-adjusted water to the solution.

The nonaqueous organic solvent is not particularly limited, if it is incompatible with water and dissolves the organic silane compound according to the present invention, and examples thereof include hexane, chloroform, carbon tetrachloride, and the like.

After the unimolecular film is formed, the unreacted organic silane compound in the unimolecular film is normally washed and removed by using a nonaqueous organic solvent. The film is washed additionally with water and dried as it is left or heated.

### EXAMPLES

### Example 1

### Preparation of triethoxysilyldibenzoperylene

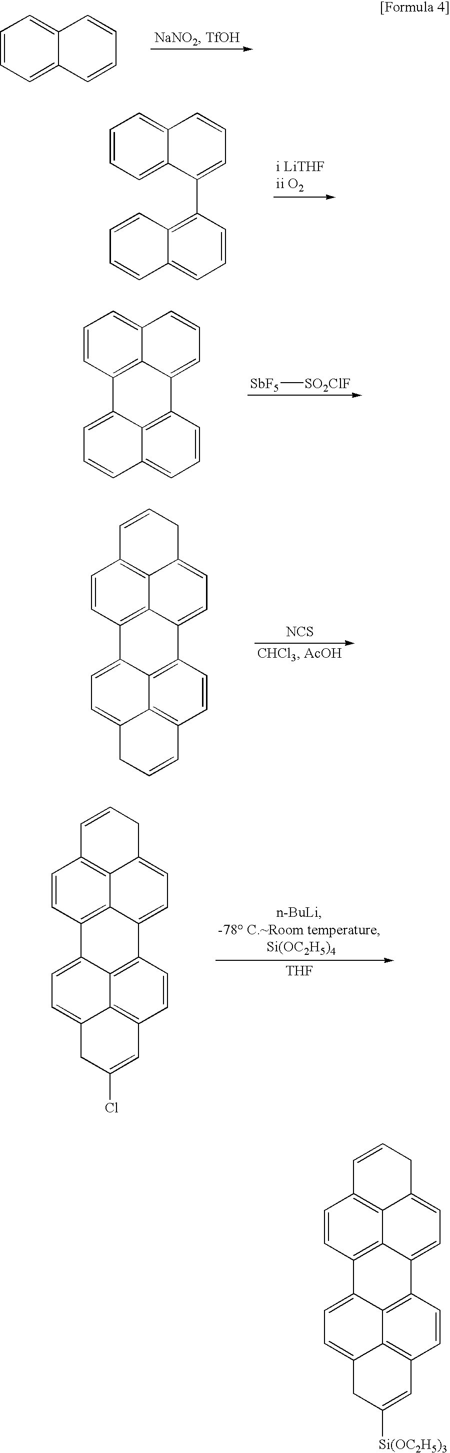

The compound was prepared according to the synthetic route 1. Specifically, naphthalene (Sigma-Aldrich Corporation) was allowed to react in NaNO₂-TfOH (Tf=CF₃SO₂) solution, to give binaphthyl from naphthalene. Binaphthyl was allowed to react in the presence of LiTHF under oxygen bubbling, to give perylene. SbF₅ purchased from Sigma-Aldrich Corporation was diluted twice under dry argon atmosphere. SO₂ClF was prepared from SO₂Cl₂ previously prepared in halogen exchange reaction between NH₄F and TFA. Perylene was allowed to react with SbF₅—SO₂ClF, and the product was purified by HPLC, to give dibenzoperylene. One equivalence of NCS with respect to dibenzoperylene was allowed to react with dibenzoperylene in AcOH in the presence of CHCl₃ for chlorination. The product was then allowed to react with n-BuLi and Si(OC₂H₅)₄ in THF solution, to give triethoxylsilyldibenzoperylene (yield: 8%).

Infrared absorption analysis revealed that the compound obtained had Si—O—C absorption at a wavelength of 1,050 nm, indicating that the compound obtained contained a silyl group.

Ultraviolet-visible absorption spectrum analysis of the chloroform solution containing the compound showed absorption at a wavelength of 378 nm. The absorption, which corresponds to π−π* transition of the dibenzoperylene skeleton contained in the molecule, confirmed that the compound contained the dibenzoperylene skeleton.

The compound was further analyzed by nuclear magnetic resonance (NMR).

7.8 ppm (m) (5H, derived from aromatic ring)

7.4 ppm (m) (2H, derived from aromatic ring)

7.1 ppm (m) (2H, derived from aromatic ring)

6.3 ppm (m) (2H, derived from aromatic ring)

3.8 ppm (m) (6H, derived from methylene group in ethoxy group)

3.6 ppm (m) (2H, derived from aromatic ring)

1.3 ppm (m) (9H, derived from methyl group in ethoxy group)

These results confirmed that the compound was triethoxysilyldibenzoperylene.

### Example 2

### Preparation of trichlorosilylcoronene

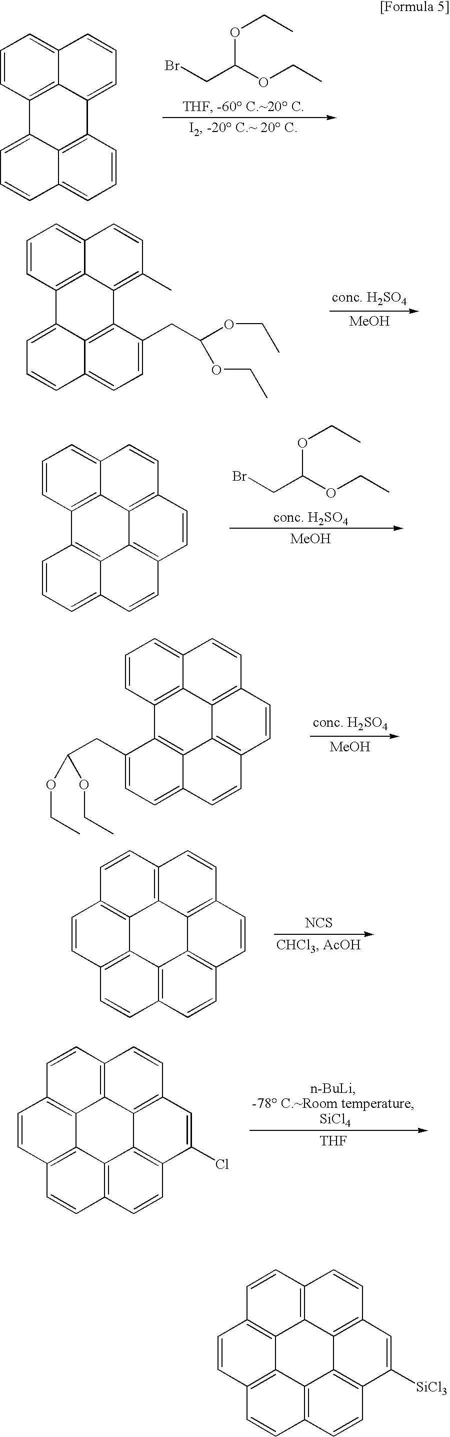

The compound was prepared according to the synthetic route 2. Specifically, the perylene prepared in Example 1 was anionized by mixing it with an electrophilic agent in bromoacetaldehyde diethyl acetal and treated with molecular iodine, to give 1-perylene acetaldehyde diethyl acetal and its 3-isomer. The 1- and 3-perylene acetaldehyde diethyl acetals were dissolved in conc. sulfuric acid/methanol mixed solvent and ultrasonicated for 1 hour, to give benzoperylene. Similarly, the benzoperylene obtained was anionized and treated with molecular iodine, to give 5- and 7-benzoperylene acetaldehyde diethyl acetals, and these benzoperylene derivatives were ultrasonicated and purified by recrystallization from toluene, to give coronene. One equivalence of NCS with respect to the coronene was allowed to react with coronene in the presence of CHCl₃ in AcOH for chlorination. The product was then allowed to react with n-BuLi and SiCl₄ in THF solution, to give trichlorosilylcoronene (yield: 46%).

Infrared absorption analysis of the compound obtained showed Si—C absorption at a wavelength of 700 nm, indicating that the compound obtained contained a silyl group.

Ultraviolet-visible absorption spectrum analysis of the chloroform solution containing the compound showed absorption at wavelengths of 338 and 300 nm. The absorption, which corresponds to π−π* transition of the coronene skeleton contained in the molecule, confirmed that the compound contained the coronene skeleton.

The compound was further analyzed by nuclear magnetic resonance (NMR).

7.4 ppm (m) (11H, derived from aromatic ring)

These results confirmed that the compound was triethoxysilylcoronene.

### Example 3

An organic thin film was formed by using the compound prepared in Example 2. Trichlorosilylcoronene was first dissolved in chloroform solvent, to give a sample solution at a concentration of 2 mM. Then, the sample solution was added dropwise in a certain amount (e.g., 100 μl) onto the water surface in a trough, forming an unimolecular film (L film) of the compound on the water surface. Pressure was applied on the water surface in that state to a particular surface pressure (e.g., 20 mN/m²), and the substrate was withdrawn at a constant speed, to form an organic thin film (LB film) shown in FIG. 1. The substrate was hydrophilized previously by immersing it in hydrogen peroxide/conc. sulfuric acid mixed solution.

AFM analysis of the trichlorosilylcoronene organic thin film formed showed a difference in height of approximately 2.6 nm. In addition, AFM and ED analysis showed periodic orientation of the constituent atoms on the film, indicating that an oriented organic thin film was formed.

Methods of preparing triethoxysilyldibenzoperylene and trichlorosilylcoronene are shown in Examples 1 and 2. An example of using trichlorosilylcoronene as an organic thin film material was shown in Example 3. However, these Examples are not to be construed that the invention is limited to the compounds above, and it is possible to prepare other organic silane compounds according to the present invention by a similar method. It is also possible to form an organic thin film by a method similar to that in Example 3 by using an organic silane compound according to the present invention as a thin film material.

Because the organic thin film of the organic silane compound according to the present invention is highly oriented and neighboring molecules are not bound to each other in the fused polycyclic aromatic hydrocarbon molecule region, which is responsible for electroconductivity, the film is obviously useful, for example, as a semiconductor layer. In such a case, it is possible to prepare a device superior in characteristics, for example, higher in carrier mobility and lower in leak current.

### INDUSTRIAL APPLICABILITY

The organic silane compound according to the present invention, which gives an oriented organic thin film easily, can be used widely not only in organic thin film transistors but also in solar cell, fuel cell, sensor, and others as a electroconductivity or semiconductor material.

What is claimed is:

1. An organic silane compound, characterized in that a fused polycyclic aromatic hydrocarbon molecule represented by General Formula (I) is substituted with a silyl group represented by General Formula:
—SiR¹R²R³
(wherein, R¹ to R³ each independently represents a halogen atom or an alkoxy group having 1 to 4 carbon atoms); 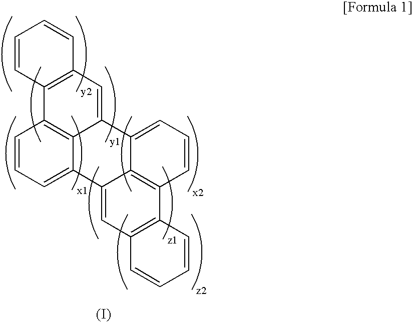
(wherein, x1 and x2 are integers respectively satisfying 1≦x1, 1≦x2, and 2≦x1+x2≦8; each of y1 and z1 is independently an integer of 2 to 8; each of y2 and z2 is independently an integer of 0 to 8; and the molecule may be substituted with a hydrophobic group).

2. A method of producing the organic silane compound according to claim 1, comprising halogenating a fused polycyclic aromatic hydrocarbon molecule and introducing an silyl group in reaction thereof with a compound represented by General Formula (α);
X¹—SiR¹R²R³ (α)
(wherein, X¹ represents a hydrogen or halogen atom or an alkoxy group having 1 to 4 carbon atoms; and R¹ to R³ each independently represents a halogen atom or an alkoxy group having 1 to 4 carbon atoms).

3. An organic thin film, comprising the organic silane compound according to claim 1 formed on a substrate, wherein the organic silane compound molecule is oriented with its silyl group located in the substrate side and the fused polycyclic aromatic hydrocarbon molecule region in the film surface side.
